(19) United States
(12) Patent Application Publication
(10) Pub. No.: US 2011/0101498 A1
(43) Pub. Date: May 5, 2011

(54) SEMICONDUCTOR DEVICE AND ARRANGEMENT METHOD THEREOF

(75) Inventors: Yugo Hayashi, Tokyo (JP); Junichi Omata, Tokyo (JP)

(73) Assignee: MITSUMI ELECTRIC CO., LTD., TOKYO (JP)

(21) Appl. No.: 13/002,344

(22) PCT Filed: Jun. 30, 2009
(86) PCT No.: PCT/JP2009/061984

§ 371 Date: Jan. 3, 2011

(30) Foreign Application Priority Data
Jul. 8, 2008 (JP) 2008-178308

(51) Int. Cl. H01L 29/66; G06F 17/50

(52) U.S. Cl. 257/531; 716/122; 257/E29.166

(57) ABSTRACT

An arrangement method of a semiconductor device including external connection terminals and inductors, the terminals being arranged at a predetermined pitch in a lattice pattern is provided. The method includes determining the arrangement of the terminals, determining a maximum width of air-core portions of the inductors, drawing first virtual lines passing a central position between two adjacent ones of the terminals in a first direction, drawing second virtual lines passing a central position between two adjacent ones of the terminals in a direction orthogonal to the first direction, determining a permissible range of distances between the first and second virtual lines nearest to each inductor and the inductor center, and arranging the inductors such that at least one of a distance between the nearest first virtual line and the inductor center and a distance between the nearest second virtual line and the inductor center falls within the permissible range.

### TECHNICAL FIELD

The present disclosure relates to a semiconductor device including plural external connection terminals and plural inductors, and an arrangement method of the semiconductor device.

### BACKGROUND ART

In recent years, miniaturization, slimming down and weight reduction of semiconductor application products are progressing rapidly to produce various mobile appliances, such as digital cameras, cellular phones, etc. In connection with this, miniaturization and high-density arrangement of semiconductor devices are also demanded, and there has been proposed a semiconductor device of a certain type that is fabricated to have a size, in its plan view, which is nearly equal to a size of a semiconductor chip mounted therein. The semiconductor device of this type is called a chip-size package (CSP).

In the following, a semiconductor device according to the related art will be explained with reference to the accompanying drawing. FIG. 1 is a cross-sectional view illustrating the composition of a semiconductor device according to the related art. The semiconductor device 100 according to the related art as illustrated in FIG. 1 is a chip-size package (CSP), and this semiconductor device 100 includes a semiconductor chip 101, an internal connection terminal 102, a first insulating layer 103, a wiring pattern 104, a second insulating layer 105, and an external connection terminal 106.

The semiconductor chip 101 includes a slimmed-down semiconductor substrate 200, a semiconductor integrated circuit 201, an electrode pad 202, an inductor 203, and a protection film 204. For example, the semiconductor substrate 200 is formed by cutting a slimmed-down Si wafer into pieces.

The semiconductor integrated circuit 201 is disposed on the upper surface of the semiconductor substrate 200. The semiconductor integrated circuit 201 is constructed by a diffusion layer, an insulating layer, vias, a wiring (not illustrated), etc. The electrode pad 202 and the inductor 203 are formed on the semiconductor integrated circuit 201. The electrode pad 202 and the inductor 203 are electrically connected to the wiring (not illustrated) formed in the semiconductor integrated circuit 201. The protection film 204 is formed on the semiconductor integrated circuit 201. The protection film 204 is a film for protecting the semiconductor integrated circuit 201.

The internal connection terminal 102 is formed on the electrode pad 202. The upper end face of the internal connection terminal 102 is exposed from the first insulating layer 103. The upper end face of the internal connection terminal 102 is connected to the wiring pattern 104. The first insulating layer 103 is disposed to cover the surface of the semiconductor chip 101 on which the internal connection terminal 102 is formed. The wiring pattern 104 is formed on the first insulating layer 103. The wiring pattern 104 is connected to the internal connection terminal 102. The wiring pattern 104 is electrically connected to the electrode pad 202 via the internal connection terminal 102.

The second insulating layer 105 is formed on the first insulating layer 103 to cover the wiring pattern 104. The second insulating layer 105 includes an opening 105x, and a part of the wiring pattern 104 is exposed in the opening 105x. The external connection terminal 106 is disposed on the wiring pattern 104 within the opening 105x. The external connection terminal 106 is connected to the wiring pattern 104. For example, refer to Patent Document 1 listed below.
Patent Document 1. Japanese Laid-Open Patent Publication No. 2006-324572

### DISCLOSURE OF THE INVENTION

### Problem to be Solved by the Invention

However, in the semiconductor device 100 according to the related art, the arrangement of the inductor 203 is not optimized, and, as illustrated in FIG. 1, the position where the inductor 203 is arranged overlaps with the external connection terminal 106 in the plan view.

In such a case, if a current flows through the inductor 203, the magnetic flux is generated and penetrates the external connection terminal 106, and this causes occurrence of an eddy current in the external connection terminal 106. As a result, the magnetic coupling between the inductor 203 and the external connection terminal 106 arises, and there is the problem that the characteristics of the inductor 203 may degrade.

A remedial measure against the problem may be taken by increasing the number of turns of the inductor 203. However, this does not serve as a fundamental solution of the problem. If the number of turns of the inductor 203 is increased, the area of the portion where the inductor 203 is formed, the resistance component produced in the inductor 203, the mutual inductance of the inductor 203 with an eddy current, etc. are also increased, which causes the Q value of the inductor 203 to deteriorate.

Accordingly, in one aspect, the present disclosure provides a semiconductor device and an arrangement method thereof which are capable of effectively preventing the degradation of the characteristics of the inductors due to the magnetic coupling between the inductors and the external connection terminals.

### Means to Solve the Problem

In an embodiment which solves or reduces one or more of the above-mentioned problems, the present disclosure provides an arrangement method of a semiconductor device (10) which includes plural external connection terminals (16) and plural inductors (23), the external connection terminals (16) being arranged in a lattice pattern at a predetermined pitch (1), the method including: a first step of determining the arrangement of the external connection terminals (16); a second step of determining a maximum width of air-core portions (23a) of the inductors (23); a third step of drawing first virtual lines (26a) each passing a nearly central position between two adjacent ones of the external connection terminals (16) in a first direction; a fourth step of drawing second virtual lines (26b) each passing a nearly central position between two adjacent ones of the external connection terminals (16) in a second direction nearly orthogonal to the first direction; a fifth step of determining a permissible range of distances (na, nb) between one of the first virtual lines (26a) and the second virtual lines (26b) nearest to each of the inductors (23) and a center (23b) of the inductor (23); and a sixth step of arranging the inductors (23) such that at least one of a distance (na) between one of the first virtual lines (26a) nearest to each of the inductors (23) and the center (23b) of the inductor (23) and a distance (nb) between one of the second virtual lines (26b) nearest to each of the inductors (23) and the center (23b) of the inductor (23) falls within the permissible range.

In an embodiment which solves or reduces one or more of the above-mentioned problems, the present disclosure provides an arrangement method of a semiconductor device (40) including plural external connection terminals (16) and plural inductors (23, 29), the semiconductor device having a first region in which the external connection terminals (16) are arranged in a lattice pattern at a first pitch (l₁), and a second region in which the external connection terminals (16) are arranged in a lattice pattern at a second pitch (l₂) that is larger than the first pitch (l₁), the method including: a first step of determining the arrangement of the external connection terminals (16) in the first region and the second region; a second step of determining a maximum width of air-core portions (23a) of the inductors (23) arranged in the first region and a maximum width of air-core portions (29a) of the inductors (29) arranged in the second region; a third step of drawing first virtual lines (26a) in the first region, each passing a nearly central position between two adjacent ones of the external connection terminals (16) in a first direction, and drawing third virtual lines (26c) in the second region, each passing a nearly central position between two adjacent ones of the external connection terminals (16) in the first direction; a fourth step of drawing second virtual lines (26b) in the first region, each passing a nearly central position between two adjacent ones of the external connection terminals (16) in a second direction nearly orthogonal to the first direction, and drawing fourth virtual lines (26d) in the second region, each passing a nearly central position between two adjacent ones of the external connection terminals (16) in the second direction; a fifth step of computing, in the first region, a permissible range A of distances (na₁, nb₁) between one of the first virtual lines (26a) and the second virtual lines (26b) nearest to each of the inductors (23) and a center (23b) of the inductor (23), and computing, in the second region, a permissible range B of distances (na₂, nb₂) between one of the third virtual lines (26c) and the fourth virtual lines (26d) nearest to each of the inductors (29) and a center (29b) of the inductor (29); and a sixth step of arranging the inductors (23) in the first region such that at least one of a distance (na₁) between one of the first virtual lines (26a) nearest to each of the inductors (23) and the center (23a) of the inductor (23) and a distance (nb₁) between one of the second virtual lines (26b) nearest to each of the inductors (23) and the center (23b) of the inductor (23) falls within the permissible range A, and arranging the inductors (29) in the second region such that at least one of a distance (na₂) between one of the third virtual lines (26c) nearest to each of the inductors (29) and the center (29b) of the inductor (29) and a distance (26d) between one of the fourth virtual lines (26d) nearest to each of the inductors (29) and the center (29b) of the inductor (29) falls within the permissible range B.

In an embodiment which solves or reduces one or more of the above-mentioned problems, the present disclosure provides a semiconductor device (10) including plural external connection terminals (16) and plural inductors (23), the external connection terminals (16) being arranged in a lattice pattern at a predetermined pitch (l), wherein the inductors (23) are arranged such that, assuming that d denotes a maximum width of air-core portions (23a) of the inductors (23), na denotes a distance between one of first virtual lines (26a) nearest to each of the inductors (23) and a center (23b) of the inductor (23), each of the first virtual lines (26a) being drawn to pass a nearly central position between two adjacent ones of the external connection terminals (16) in a first direction, and nb denotes a distance between one of second virtual lines (26b) nearest to each of the inductors (23) and the center (23b) of the inductor (23), each of the second virtual lines (26b) being drawn to pass a nearly central position between two adjacent ones of the external connection terminals (16) in a second direction nearly orthogonal to the first direction, the maximum width d satisfies the Inequality 1 below and the distances na and nb satisfy the Inequalities 2 and 3 below respectively,

d≦l−r Inequality 1

na≦{l−(d+r)}/2 Inequality 2

nb≦{l−(d+r)}/2 Inequality 3

where l denotes a pitch between two adjacent ones of the external connection terminals (16) in the first direction and the second direction and r denotes a maximum diameter of the external connection terminals (16) in a plan view.

In an embodiment which solves or reduces one or more of the above-mentioned problems, the present disclosure provides a semiconductor device (40) including plural external connection terminals (16) and plural inductors (23, 29), the semiconductor device having a first region in which the external connection terminals (16) are arranged in a lattice pattern at a first pitch (l₁), and a second region in which the external connection terminals (16) are arranged in a lattice pattern at a second pitch (l₂) which is larger than the first pitch (l₁), wherein the inductors (23) are arranged in the first region such that, assuming that d₁ denotes a maximum width of air-core portions (23a) of the inductors (23) in the first region, na₁ denotes a distance between one of first virtual lines (26a) nearest to each of the inductors (23) and a center (23b) of the inductor (23), each of the first virtual lines (26a) being drawn to pass a nearly central position between two adjacent ones of the external connection terminals (16) in a first direction, and nb₁ denotes a distance between one of second virtual lines (26b) nearest to each of the inductors (23) and the center (23b) of the inductor (23), each of the second virtual lines (26b) being drawn to pass a nearly central position between two adjacent ones of the external connection terminals (16) in a second direction nearly orthogonal to the first direction, the maximum width d₁ satisfies the Inequality 4 below and the distances na₁ and nb₁ satisfy the Inequalities 5 and 6 below respectively, and wherein, assuming that d₂ denotes a maximum width a maximum width of air-core portions (29a) of the inductors (29) in the second region, na₂ denotes a distance between one of third virtual lines (26c) nearest to each of the inductors (29) and a center (29b) of the inductor (29), each of the third virtual lines (26c) being drawn to pass a nearly central position between two adjacent ones of the external connection terminals (16) in the second region in the first direction, and nb₂ denotes a distance between one of fourth virtual lines (26d) nearest to each of the inductors (29) and the center (29b) of the inductor (29), each of the fourth virtual lines (26d) being drawn to pass a nearly central position between two adjacent ones of the external connection terminals (16) in the second region in the second direction, the maximum width d₂ satisfies the Inequality 7 below and the distances na₂ and nb₂ satisfy the Inequalities 8 and 9 below respectively,

d₁≦l₁−r Inequality 4

na₁≦{l₁−(d₁+r)}/2 Inequality 5

nb₁≦{l₁−(d₁+r)}/2 Inequality 6

d₂≦l₂−r Inequality 7

na₂≦{l₁−(d₂+r)}/2 Inequality 8

nb₂≦{l₁−(d₂+r)}/2 Inequality 9

where l denotes a pitch between two adjacent ones of the external connection terminals (16) in the first region in the first direction and the second direction, l₂ denotes a pitch between two adjacent ones of the external connection terminals (16) in the second region in the first direction and the second direction, and r denotes a maximum diameter of the external connection terminals (16) in a plan view.

It is to be understood that the reference numerals in parentheses in the foregoing general description are exemplary and explanatory and are not restrictive of the present disclosure.

### Effect of the Invention

According to the present disclosure, it is possible to provide a semiconductor device and an arrangement method thereof which are capable of effectively preventing the degradation of the characteristics of the inductors due to the magnetic coupling between the inductors and the external connection terminals.

### BRIEF DESCRIPTION OF THE DRAWINGS

FIG. 1 is a cross-sectional view illustrating the composition of a semiconductor device according to the related art.

FIG. 2 is a cross-sectional view illustrating the composition of a semiconductor device of a first embodiment of the present disclosure.

FIG. 3 is a plan view illustrating a semiconductor substrate in which the semiconductor device of the first embodiment is formed.

FIG. 4 is a diagram illustrating the positional relationship between inductors and external connection terminals in the semiconductor device of the first embodiment.

FIG. 5 is a diagram illustrating the magnetic flux generated when a current flows through an inductor.

FIG. 6 is a flowchart for explaining an arrangement method of arranging external connection terminals and inductors.

FIG. 7 is a diagram illustrating the method of arranging the external connection terminals and the inductors.

FIG. 8 is a diagram illustrating the method of arranging the external connection terminals and the inductors.

FIG. 9 is a diagram illustrating the method of arranging the external connection terminals and the inductors.

FIG. 10 is a diagram illustrating the method of arranging the external connection terminals and the inductors.

FIG. 11 is a diagram illustrating the method of arranging the external connection terminals and the inductors.

FIG. 12 is a diagram illustrating an inductor model.

FIG. 13 is a diagram illustrating a distribution of magnetic flux density of an air-core portion of the inductor model illustrated in FIG. 12.

FIG. 14 is a diagram illustrating the positional relationship between an inductor and adjacent external connection terminals.

FIG. 15A is a diagram illustrating the positional relationship between an inductor and adjacent external connection terminals.

FIG. 15B is a diagram illustrating the positional relationship between an inductor and adjacent external connection terminals.

FIG. 16 is a diagram illustrating the positional relationship between inductors and external connection terminals arranged in a semiconductor device of a second embodiment of the present disclosure.

FIG. 17 is a diagram illustrating the state in which inductors are arranged.

FIG. 18 is a diagram illustrating the state in which inductors are arranged in an irregular formation.

### BEST MODE FOR CARRYING OUT THE INVENTION

A description will be given of embodiments of the present disclosure with reference to the accompanying drawings.

### First Embodiment

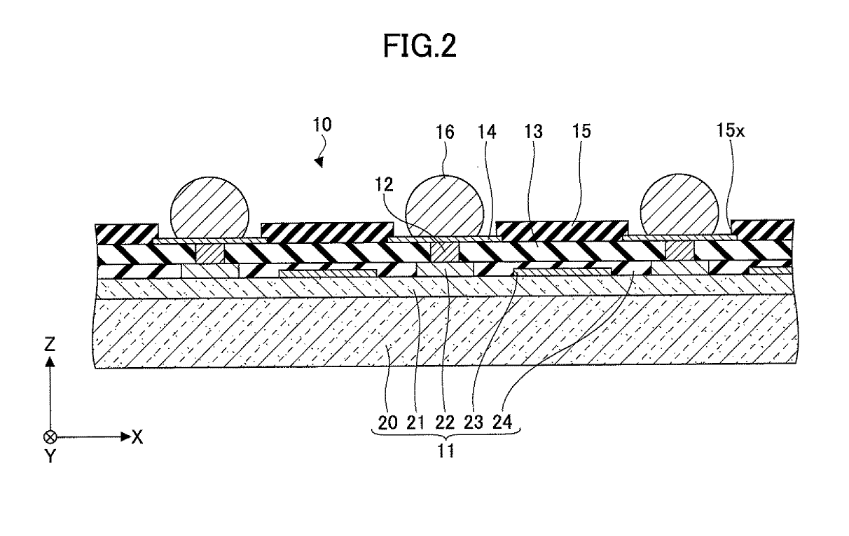

FIG. 2 is a cross-sectional view illustrating the composition of a semiconductor device of a first embodiment of the present disclosure. As illustrated in FIG. 2, the semiconductor device 10 is a wafer-level chip-size package (WLCSP), and this semiconductor device 10 includes a semiconductor chip 11, internal connection terminals 12, a first insulating layer 13, a wiring pattern 14, a second insulating layer 15, and external connection terminals 16. The wafer-level chip-size package (WLCSP) is a kind of the chip-size package (CSP), and this package is constructed by forming wiring, external connection terminals, etc. on a semiconductor substrate (for example, a silicon wafer) in which a semiconductor chip is incorporated, and subsequently by cutting the semiconductor substrate into pieces.

The semiconductor chip 11 includes a semiconductor substrate 20, a semiconductor integrated circuit 21, electrode pads 22, inductors 23, and a protection film 24. The semiconductor substrate 20 is a substrate for forming the semiconductor integrated circuit 21 therein. The semiconductor substrate 20 is slimmed down to have a small thickness. For example, the thickness of the semiconductor substrate 20 may be in a range of 100-300 micrometers. For example, the semiconductor substrate 20 may be formed by cutting a slimmed-down Si wafer into pieces.

The semiconductor integrated circuit 21 is formed on the upper surface of the semiconductor substrate 20. The semiconductor integrated circuit 21 includes a diffusion layer, an insulating layer, vias, a wiring (not illustrated), etc. The wiring (not illustrated) may be formed in multiple layers. The plural electrode pads 22 and the plural inductors 23 are formed on the semiconductor integrated circuit 21. The electrode pads 22 and the inductors 23 are electrically connected to the wiring (not illustrated) formed in the semiconductor integrated circuit 21. For example, Cu, Al, etc. may be used as a material of the electrode pads 22 and the inductors 23.

The protection film 24 is a film for protecting semiconductor integrated circuit 21, and this protection film 24 is formed on the semiconductor integrated circuit 21. The protection film 24 may be called a passivation film. For example, a SiN film, a PSG film, etc. may be used as a material of the protection film 24. Alternatively, a layer of polyimide may be additionally laminated on a layer of a SiN film or a PSG film in the protection film 24. The upper end face of the electrode pad 22 is exposed from the protection film 24.

The internal connection terminals 12 are formed on the electrode pads 22 respectively. The internal connection terminals 12 are formed to establish the electrical connection between the semiconductor integrated circuit 21 and the wiring pattern 14. For example, Au bumps, etc. may be used as a material of the internal connection terminals 12. The upper end face of each of the internal connection terminals 12 is exposed from the first insulating layer 13. The upper end faces of the internal connection terminals 12 are connected to the wiring pattern 14.

The first insulating layer 13 is formed to protect the circuit formation surface (principal surface) of the semiconductor chip 11, and this first insulating layer 13 serves as a base material used when forming the wiring pattern 14. The first insulating layer 13 is formed to cover the semiconductor chip 11 and the internal connection terminals 12 except the upper end faces of the internal connection terminals 12. The upper surface of the first insulating layer 13 is nearly flush with the upper end faces of the internal connection terminals 12. For example, a sheet-like insulating resin with an adhesion property may be used as a material of the first insulating layer 13.

The wiring pattern 14 is formed on the first insulating layer 13. The wiring pattern 14 is connected to the internal connection terminals 12. The wiring pattern 14 is electrically connected to the electrode pads 22 via the internal connection terminals 12. The wiring pattern 14 may be called a re-wiring pattern. For example, Cu, etc. may be used as a material of the wiring pattern 14.

The second insulating layer 15 is formed on the first insulating layer 13 to cover the wiring pattern 14. The second insulating layer 15 includes openings 15x, and corresponding parts of the wiring pattern 14 are exposed from the openings 15x respectively. For example, an insulating thin film of a polyimide may be used as a material of the second insulating layer 15.

The external connection terminals 16 are disposed on the exposed parts of the wiring pattern 14 within the openings 15x respectively. The external connection terminals 16 are connected to the wiring pattern 14. The external connection terminals 16 are formed so that the external connection terminals 16 are electrically connected to the pads formed on an external mounting board, such as a mother board, (not illustrated). For example, an alloy containing Pb, an alloy of Sn and Cu, an alloy of Sn and Ag, etc. may be used as a material of the external connection terminals 16. Alternatively, the external connection terminals 16 may have a post-like configuration, for example.

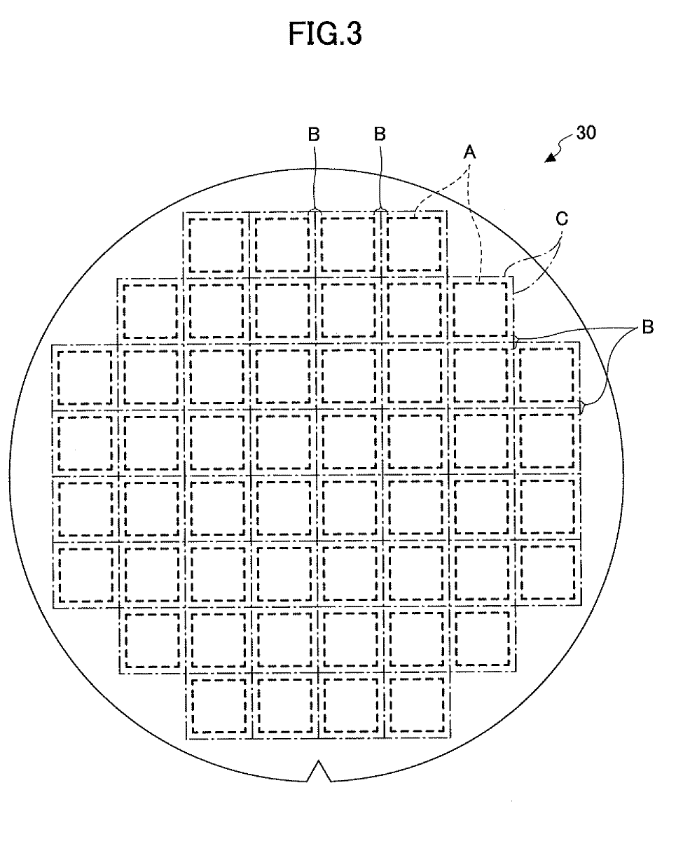

FIG. 3 is a plan view illustrating a semiconductor substrate in which the semiconductor device of the first embodiment is formed. In FIG. 3, reference numeral 30 denotes the semiconductor substrate, and character C denotes the positions (which will be referred to as “cut position C”) of the semiconductor substrate at which the semiconductor substrate 30 is cut into pieces by a dicing saw. As illustrated in FIG. 3, the semiconductor substrate 30 includes plural semiconductor device formation areas A, and plural scribe regions B in which the semiconductor device formation areas A are separated.

Each of the semiconductor device formation areas A is an area in which the semiconductor device 10 is formed. The semiconductor substrate 30 is slimmed down and cut at the cut positions C into pieces, and this semiconductor substrate 30 corresponds to the previously described semiconductor substrate 20 (refer to FIG. 2).

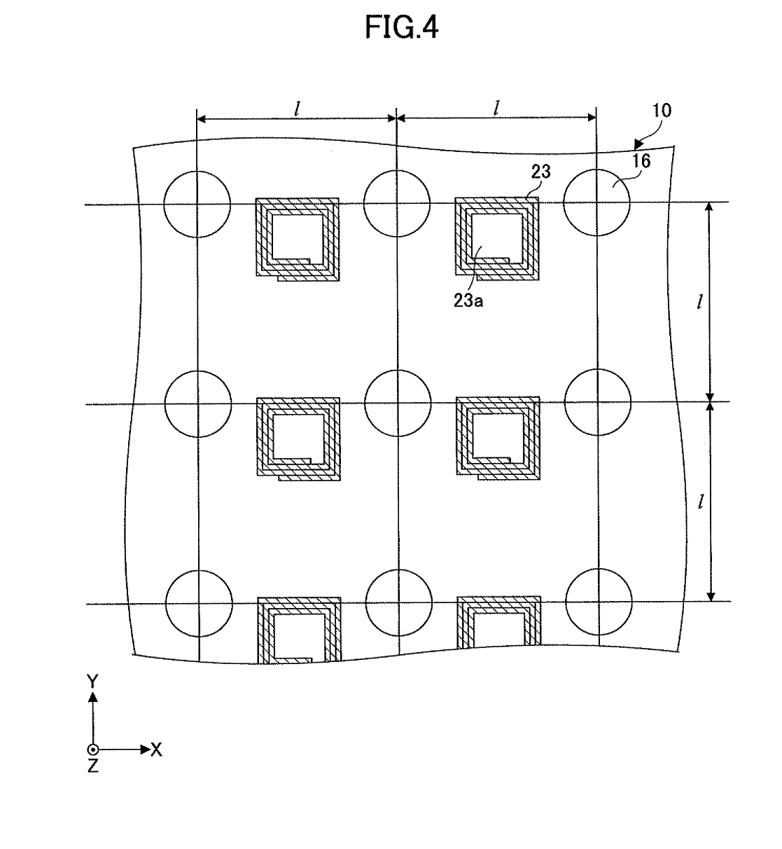

FIG. 4 is a diagram illustrating the positional relationship between inductors and external connection terminals in the semiconductor device of the first embodiment. In FIG. 4, the elements which are the same as corresponding elements in FIG. 2 are designated by the same reference numerals, and a description thereof will be omitted. FIG. 4 illustrates the positional relationship between the inductors 23 and the external connection terminals 16 when the semiconductor device 10 is viewed from the direction in FIG. 2. In the following, a view of the semiconductor device 10 when the semiconductor device 10 is viewed from the Z+ direction will be referred to as a plan view.

In FIG. 4, reference numeral 23a denotes an air-core portion of an inductor 23. This air-core portion refers to a vacant portion surrounded by the inductor 23 which is formed in a spiral configuration. As illustrated in FIG. 4, plural external connection terminals 16 in the semiconductor device 10 are arranged in a lattice pattern, and a pitch between two adjacent ones of the external connection terminals 16 in the x direction and the y direction is represented by 1. The inductors 23 are arranged such that the air-core portion 23a of each inductor 23 does not overlap with any of the external connection terminals 16 in the plan view.

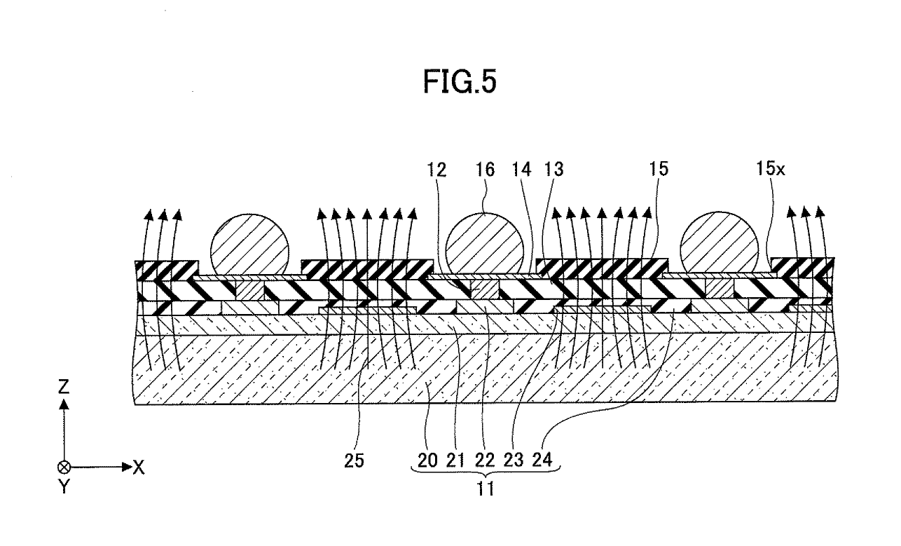

FIG. 5 is a diagram illustrating the magnetic flux generated when a current flows through an inductor.

In FIG. 5, the elements which are the same as corresponding elements in FIG. 2 are designated by the same reference numerals, and a description thereof will be omitted.

In FIG. 5, reference numeral 25 denotes the magnetic flux. When a current flows through the inductor 23 in the predetermined direction as illustrated in FIG. 5, the magnetic flux 25 is generated.

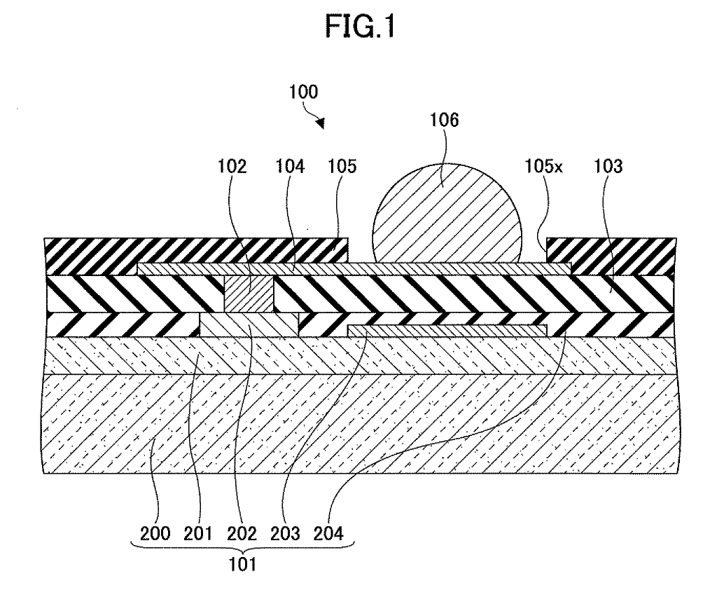

Unlike the case in which the position where the inductor 203 is arranged overlaps with the external connection terminal 106 in the plan view as in the semiconductor device 100 illustrated in FIG. 1, the semiconductor device 10 of this embodiment is arranged so that the positions where the inductors 23 are arranged do not overlap with the external connection terminals 16 in the plan view (refer to FIG. 4). Hence, the magnetic flux 25 in this embodiment does not penetrate the external connection terminals 16. Accordingly, the magnetic coupling between the inductors 23 and the external connection terminals 16 in this embodiment does not arise, and the characteristics of the inductors 23 are not degraded.

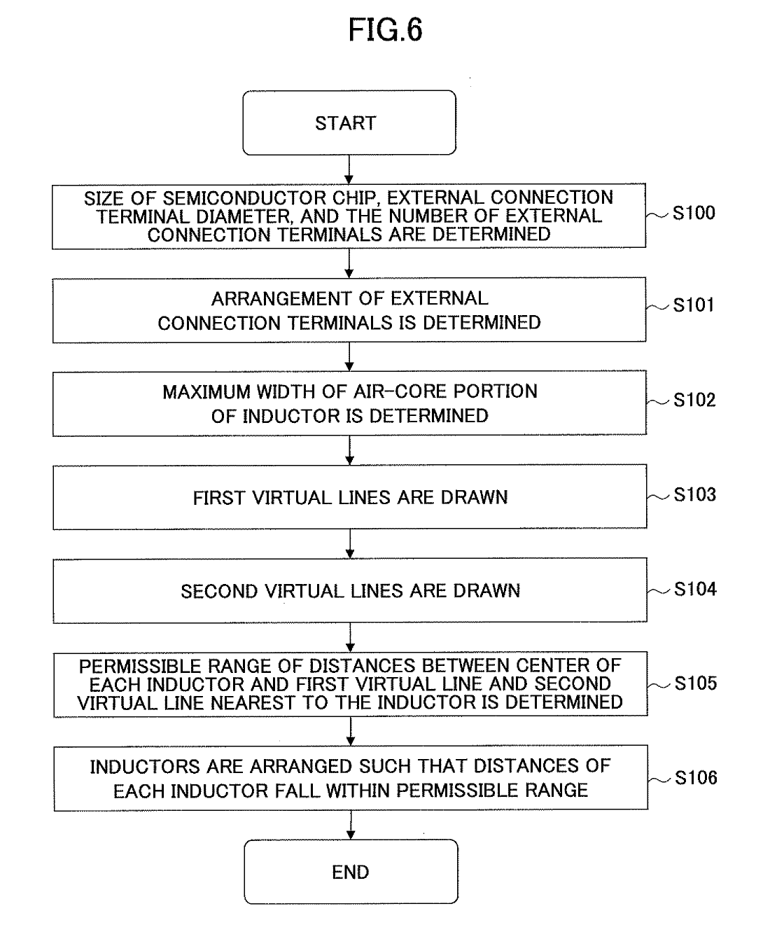

FIG. 6 is a flowchart for explaining an arrangement method of arranging external connection terminals and inductors. The arrangement method of arranging the external connection terminals 16 and the inductors 23 will be described with reference to FIG. 6.

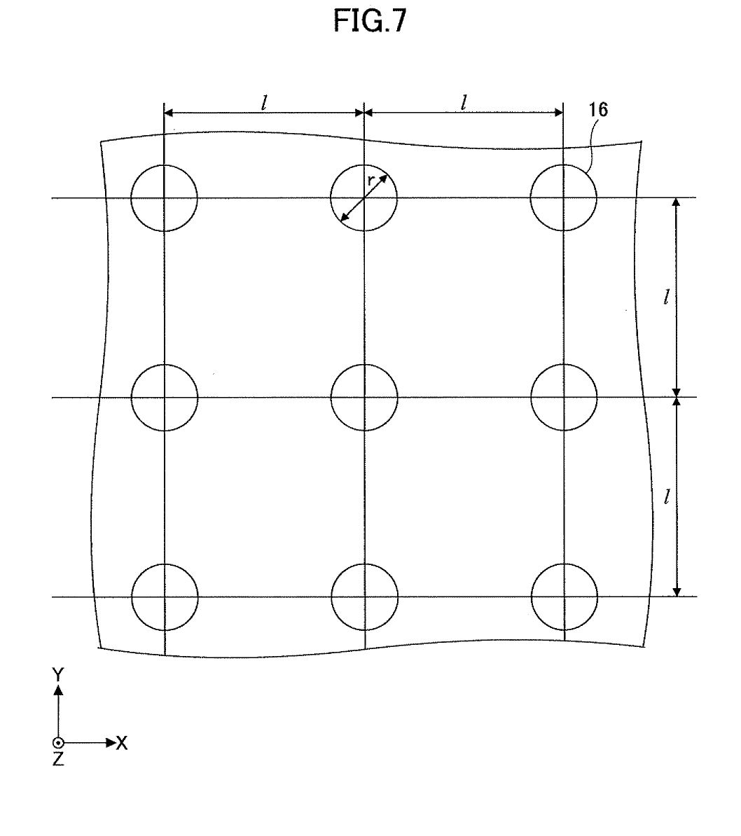

FIGS. 7-11 illustrating the method of arranging the external connection terminals and the inductors will be referred to, if needed. In FIGS. 7-11, the elements which are the same as corresponding elements in FIGS. 2-6 are designated by the same reference numerals, and a description thereof will be omitted.

In step 100, a size of the semiconductor chip 11 and a diameter r and the number of the external connection terminals 16 are determined (S100). The diameter r of the external connection terminals 16 means the diameter of each external connection terminal 16 in the plan view.

In the first embodiment, the example in which each external connection terminal 16 has a circular shape in the plan view and a diameter of its circular portion in the plan view is represented by r is illustrated. In a case in which each external connection terminal 16 has not a circular shape in the plan view, a maximum diameter of the external connection terminal 16 is used instead of the diameter r. For example, if each external connection terminal 16 has an elliptical shape in the plan view, the major diameter of the elliptical portion of the external connection terminal 16 in the plan view is equivalent to the maximum diameter.

Subsequently, in step 101, the arrangement of the external connection terminals 16 is determined (S101). For example, the external connection terminal 16 may be arranged in a lattice pattern at a pitch “1” between two adjacent ones of the external connection terminals 16 in the x direction and the y direction as illustrated in FIG. 7.

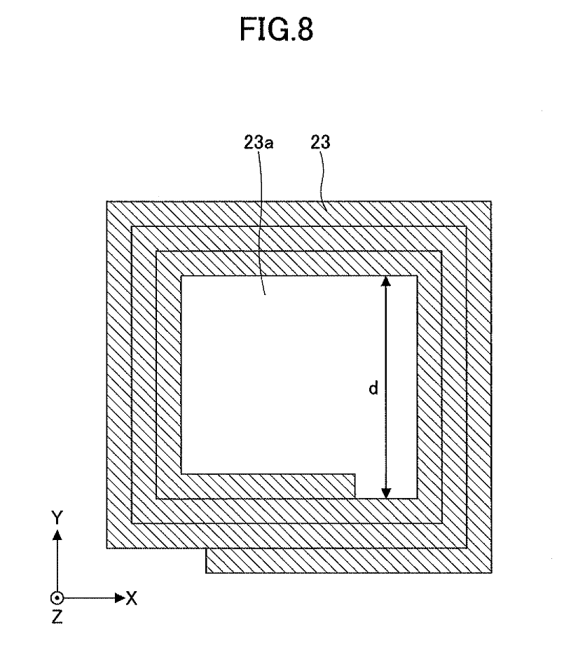

Subsequently, in step 102, a maximum width of the air-core portions 23a of the inductors 23 is determined (S102). As illustrated in FIG. 8, the maximum width d of the air-core portions 23a of the inductors 23 means the width of the largest portion of each air-core portion 23a in the x direction and the y direction. Also when the shape of the air-core portion 23a is different from that illustrated in FIG. 8, the meaning of the maximum width d is the same as illustrated in FIG. 8. For example, when the air-core portion 23a has a circular shape in the plan view, the maximum width d is equal to the diameter of the circular portion in the plan view, and when the air-core portion 23a has an elliptical or polygonal shape in the plan view, the maximum width d is equivalent to the width of the largest portion of the elliptical or polygonal portion in the plan view in the x direction and the y direction.

In the step 102, the maximum width d is determined so that the maximum width d satisfies the following Inequality 1,

d≦l−r Inequality 1

where l denotes a pitch between two adjacent external connection terminals 16 in the x direction and y direction, and r denotes a diameter of the external connection terminals 16 in the plan view.

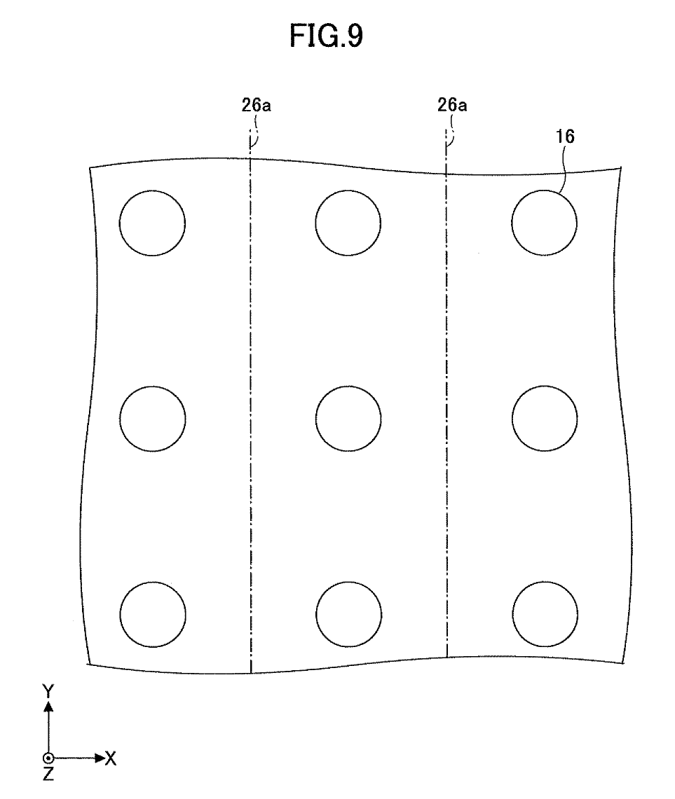

Subsequently, in step 103, first virtual lines, each passing a nearly central position between two adjacent ones of the external connection terminals 16 in a first direction, are drawn (S103). As illustrated in FIG. 9, assuming that the first direction is set to the x direction, the first virtual lines 26a each passing a nearly central position between two adjacent ones of the external connection terminals 16 in the x direction are drawn.

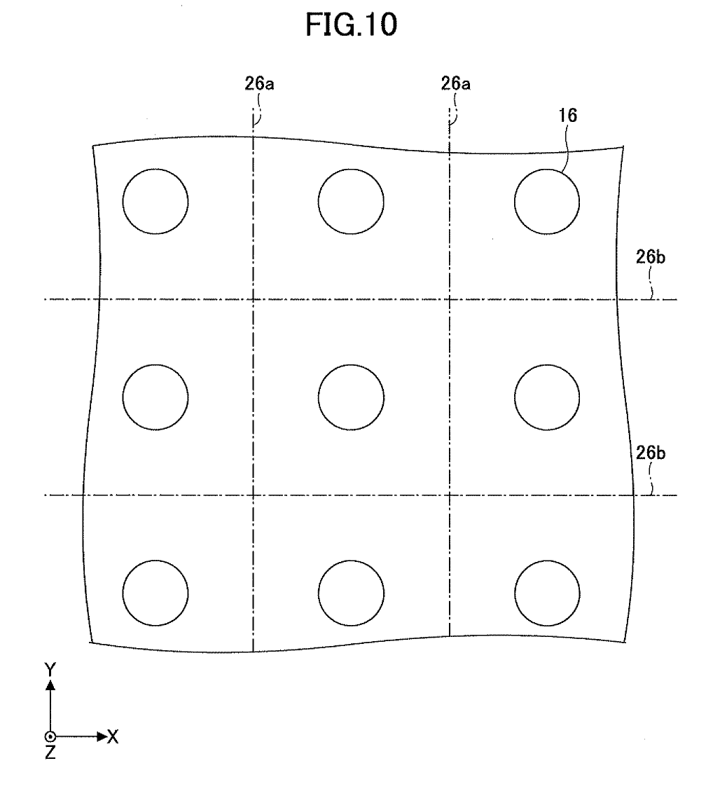

Subsequently, in step 104, second virtual lines, each passing a nearly central position between two adjacent ones of the external connection terminal 16 in a second direction nearly orthogonal to the first direction are drawn (S104). As illustrated in FIG. 10, assuming that the second direction is set to the y direction nearly orthogonal to the x direction (which is the first direction), the second virtual lines 26b each passing a nearly central position between two adjacent ones of the external connection terminals 16 in the y direction are drawn.

Subsequently, in step 105, a permissible range m of the distances between one of the first virtual lines 26a and the second virtual lines 26b nearest to each of the inductors 23 and the center of the inductor 23 is determined (S105). The permissible range m is determined to satisfy the following Equation 2,

m={l−(d+r)}/2 Equation 2

where l denotes a pitch between two adjacent ones of the external connection terminals 16 in the x direction and the y direction, r denotes a diameter of the external connection terminals in the plan view, and d denotes the maximum width of the air-core portions 23a of the inductors 23.

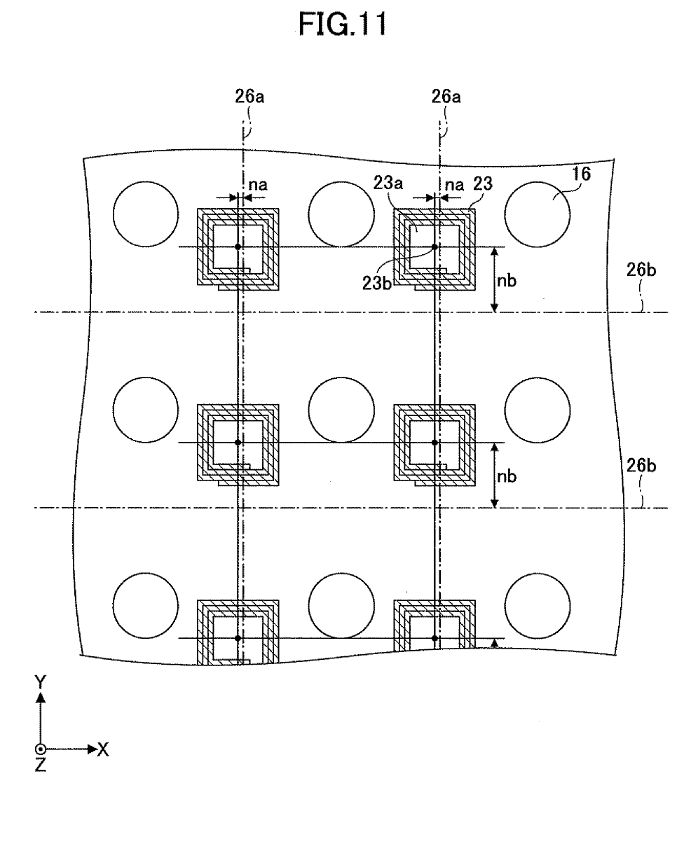

Subsequently, in step 106, as illustrated in FIG. 11, a distance na between the center 23b of the inductor 23 and the first virtual line 26a nearest to the inductor, and a distance nb between the center 23b of the inductor 23 and the second virtual line 26b nearest to the inductor are determined (S106). The distances na and nb are determined to satisfy the following Inequalities 3 and 4. That is, the distances na and nb can take arbitrary values that fall within the permissible range m, and the inductors 23 are arranged in accordance with the determined distances na and nb (S106).

na≦m Inequality 3

where m denotes a permissible range of the distances between the center 23b of each inductor 23 and one of the first virtual lines 26a and the second virtual lines 26b nearest to the inductor 23,

nb≦m Inequality 4

where m denotes a permissible range of the distances between the center 23b of each inductor 23 and one of the first virtual lines 26a and the second virtual lines 26b nearest to the inductor 23.

FIG. 11 illustrates an exemplary arrangement method in which the external connection terminals 16 and the inductors 23 are arranged so that the distance na between the center 23b of each inductor 23 and the first virtual line 26a nearest to the inductor is the same for all the inductors 23 and the distance nb between the center 23b of each inductor 23 and the second virtual line 26b nearest to the inductor is the same for all the inductors 23. However, if the condition that at least one the distances na and nb falls within the permissible range m is satisfied, the distances na and nb for the respective inductors 23 may be different. In such a case, the inductors 23 are arranged in an irregular formation with respect to the first virtual lines 26a and the second virtual lines 26b.

Next, the Inequalities 1 to 4 will be described. Because the magnetic flux generated when a current flows through the inductor is concentrated on the air-core portion of the inductor, the distribution of the magnetic flux density of the air-core portion will be described.

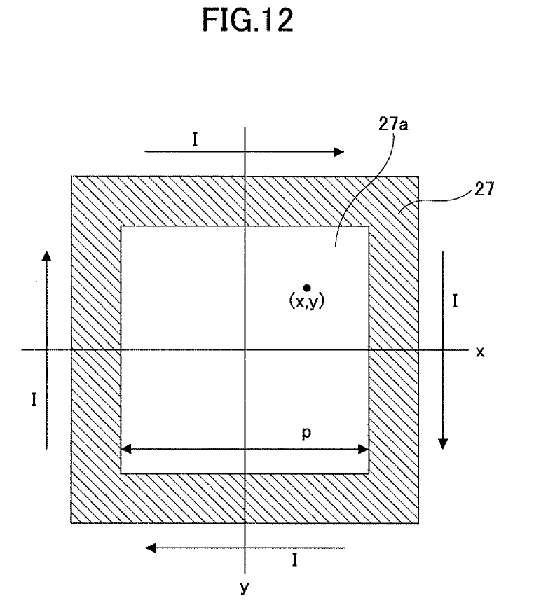

FIG. 12 is a diagram illustrating an inductor model. As illustrated in FIG. 12, the inductor model 27 is constructed to form a closed loop and includes an air-core portion 27a in the shape of a square with one side having a length of p. When a current I flows through the inductor model 27 in the direction indicated by the arrows in FIG. 12, the magnetic flux which penetrates the plane of the figure in the direction from the front side to the backside is generated according to the rule of Fleming.

The intersection of the x-axis and the y-axis is the origin of the distribution of the magnetic flux density, which is the center of the inductor model 27.

The distribution of the magnetic flux density may be determined according to the Biot-Savart law. The following Equation 5 can be derived from the Biot-Savart law,

$$\begin{matrix}{B}_{z} = az \cdot \frac{{μ}_{0}}{4 π} ∮ \frac{i \times s}{{s}^{3}} d p \\ = \frac{{μ}_{0} I}{4 π} [ \begin{matrix}\sqrt{1 / {( x + \frac{p}{2} )}^{2} + 1 / {( y + \frac{p}{2} )}^{2}} + \\ \sqrt{1 / {( x - \frac{p}{2} )}^{2} + 1 / {( y + \frac{p}{2} )}^{2}} + \\ \sqrt{1 / {( x + \frac{p}{2} )}^{2} + 1 / {( y - \frac{p}{2} )}^{2}} + \\ \sqrt{1 / {( x - \frac{p}{2} )}^{2} + 1 / {( y - \frac{p}{2} )}^{2}}\end{matrix} ]\end{matrix} \qquad Equation 5$$

where Bz denotes a magnetic flux density vector, az denotes an unit vector, μ₀ denotes a permeability of vacuum, i denotes a very small current, s denotes a distance between the point the magnetic flux density of which is to be determined and the very small current i, I denotes the current which flows through the inductor model 27, p denotes a length of one side of the air-core portion 27a, dp denotes a loop integration of the inductor model 27, and x and y denote the distances from the center of the inductor model 27 in the x direction and the y direction.

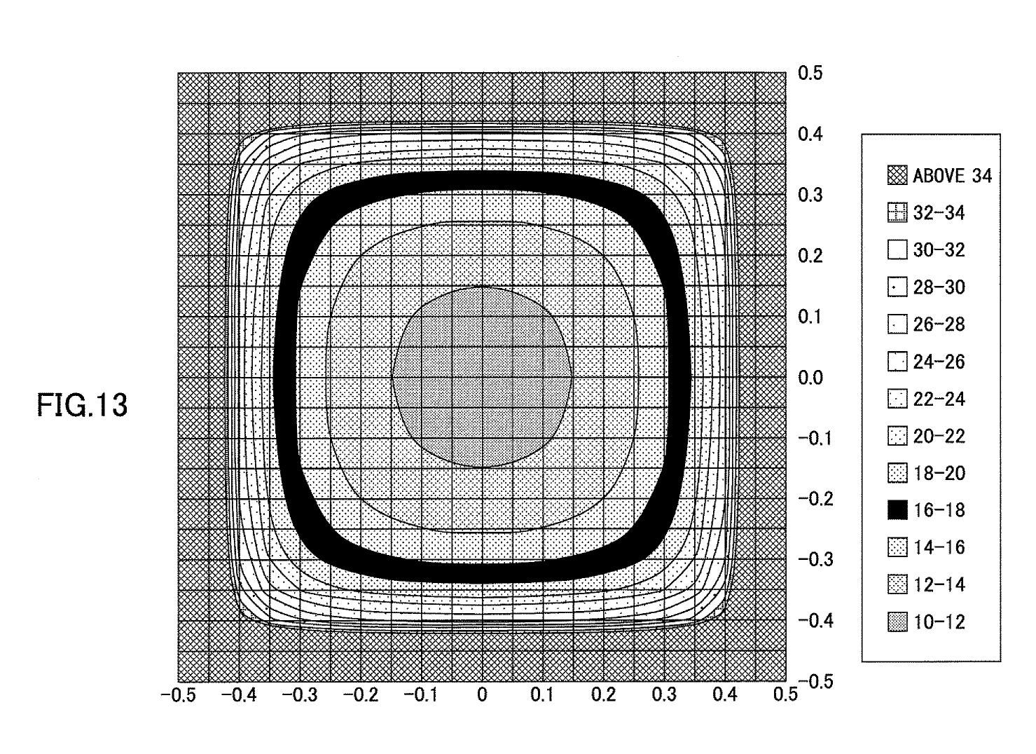

As an example, the magnetic flux density distribution in the case of the length p of one side of the square of the air-core portion 27a ˜1.0 and μ₀I/4π=1.0 is determined in accordance with the Equation 5. FIG. 13 is a diagram illustrating the magnetic flux density distribution of the air-core portion of the inductor model illustrated in FIG. 12. In FIG. 13, the horizontal axis represents the distance from the center of the inductor model 27 in the x direction, and the vertical axis represents the distance from the center of the inductor model 27 in the y direction. The numerical values of 10-34 denote the magnetic flux density and the larger the numerical value, the higher the magnetic flux density.

As illustrated in FIG. 13, the magnetic flux density of a vicinity of the central part of the air-core portion 27a (the portion of the magnetic flux density of 10-12) is the lowest, the magnetic flux density gradually increases in the outward direction toward the outside of the air-core portion 27a, and the magnetic flux density of an outer periphery of the air-core portion 27a (the portion of the magnetic flux density of 34 or larger) is the highest. This shows that, if an alternating current flows through the inductor model 27, a change of the magnetic flux density of the outer periphery of the air-core portion 27a is the maximum. Therefore, in order to reduce the influences of an eddy current, it is necessary to arrange the inductors so that the outer periphery of the air-core portion 27a may not overlap with any of the external connection terminals in the plan view.

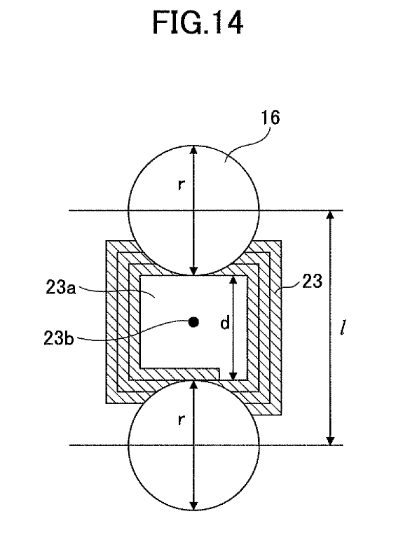

FIG. 14 is a diagram illustrating the positional relationship between an inductor and adjacent external connection terminals. In FIG. 14, the elements which are the same as corresponding elements in FIG. 11 are designated by the same reference numerals and a description thereof will be omitted.

It is readily understood from FIG. 14 that a maximum width d of the air-core portion 23a of the inductor with which the outer periphery of the air-core portion 23a and the external connection terminals 16 do not overlap with each other in the plan view is represented by d=l−r. This is illustrated as the Inequality 1 above. In FIG. 14, l denotes the pitch between the two adjacent external connection terminals 16 in the x direction and the y direction, and r denotes the diameter of the external connection terminals 16 in the plan view.

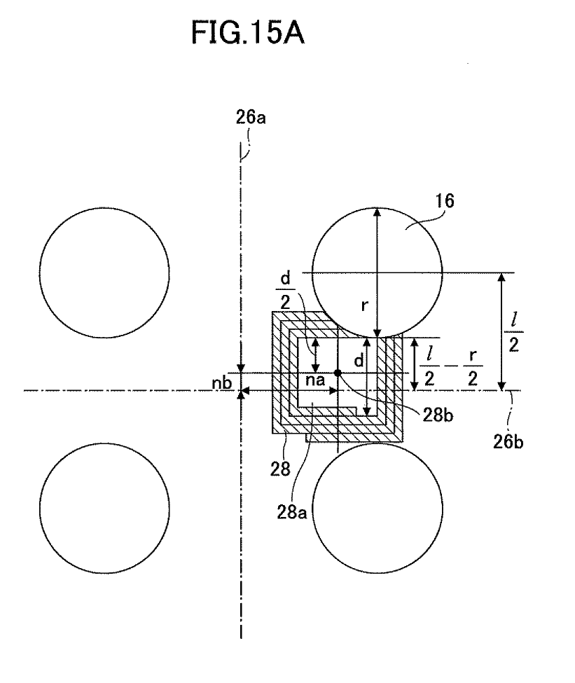

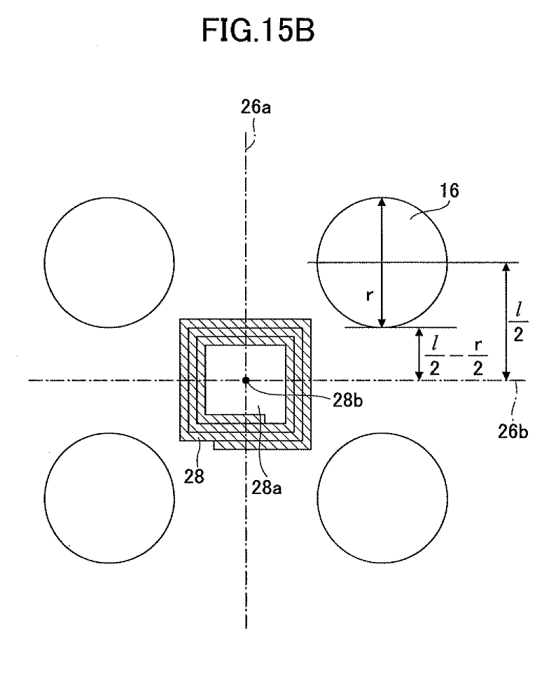

FIG. 15A is a diagram illustrating the positional relationship between an inductor and adjacent external connection terminals. FIG. 15B is a diagram illustrating the positional relationship between an inductor and adjacent external connection terminals. In FIG. 15A and FIG. 15B, the elements which are the same as corresponding elements in FIG. 11 are designated by the same reference numerals and a description thereof will be omitted. The inductor 28 illustrated in FIG. 15A and FIG. 15B is an inductor having an air-core portion 28a with a maximum width d. In FIG. 15A and FIG. 15B, reference numeral 28b denotes the center of the air-core portion 28a, na denotes the distance between the center 28b and a virtual line 26a, and nb denotes the distance between the center 28b and a virtual line 26b.

As illustrated in FIG. 15A, if (na+d/2)≦(l/2−r/2), the outer periphery of the air-core portion 28a and the external connection terminals 16 do not overlap with each other in the plan view, irrespective of the value of the distance nb. Similarly, if (nb+d/2)≦(l/2−r/2), in the plan view, the outer periphery of the air-core portion 28a and the external connection terminals 16 do not overlap with each other, irrespective of the value of the distance na. The Inequalities 2 to 4 listed above are obtained by transforming these inequalities.

In order to satisfy the condition that the outer periphery of the air-core portion 28a and the external connection terminals 16 do not overlap with each other in the plan view, it is sufficient that at least one of the distance na and the distance nb satisfies the Inequality 3 or the Inequality 4. Of course, both the distance na and the distance nb may satisfy the Inequality 3 and the Inequality 4. When either the distance na or the distance nb is equal to zero, the distance between the outer periphery of the air-core portion 28a and the external connection terminal 16 may be increased to a comparatively large value.

As illustrated in FIG. 15B, when the distance na=the distance nb=0, the center 28b of the inductor 28 is located at the intersection of the first virtual line 26a and the second virtual line 26b. At this time, the distance between the outer periphery of the air-core portion 28a of the inductor 28 and the external connection terminal 16 arranged in the vicinity of the inductor 28 is equal to the maximum, and the arrangement of the inductor 28 at this time is in the most desirable state for preventing the magnetic coupling between the inductor 28 and the external connection terminal 16.

In the semiconductor device of the first embodiment of the present disclosure including inductors, the maximum width of the air-core portions of the inductors is determined to satisfy the Inequality 1, and the inductors are arranged to satisfy at least one of the Inequality 3 and the Inequality 4. As a result, the inductors are arranged so that the outer periphery of the air-core portion of each inductor and the external connection terminals arranged in the vicinity thereof do not overlap with each other in the plan view. Therefore, the magnetic flux generated when a current flows through each of the inductors does not penetrate the external connection terminals and an eddy current does not occur in the external connection terminals. It is possible to effectively prevent the degradation of the characteristics of the inductors due to the magnetic coupling between the inductors and the external connection terminals.

### Second Embodiment

In the first embodiment of the present disclosure, the semiconductor device in which respective pitches between two adjacent ones of external connection terminals in the x direction and the y direction are equal to each other is illustrated. In a second embodiment of the present disclosure, a semiconductor device including two distinct regions in which respective pitches between two adjacent ones of external connection terminals in the x direction and the y direction differ from each other is illustrated.

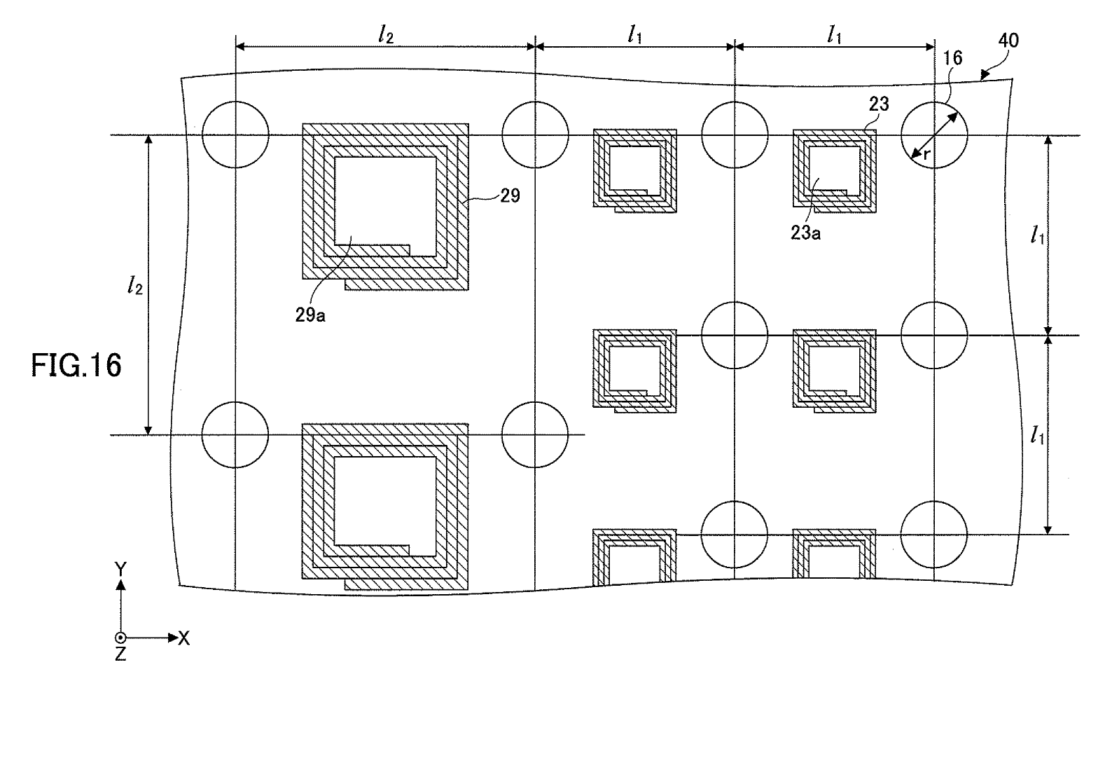

FIG. 16 is a diagram illustrating the positional relationship between inductors and external connection terminals arranged in a semiconductor device of a second embodiment of the present disclosure. In FIG. 16, the elements which are the same as corresponding elements in FIG. 4 are designated by the same reference numerals and a description thereof will be omitted. In FIG. 16, reference numeral 29 denotes an inductor and reference numeral 29a denotes an air-core portion of the inductor 29.

As illustrated in FIG. 16, the semiconductor device 40 includes two distinct regions (which will be referred to as first and second regions) in which respective pitches between two adjacent ones of external connection terminals 16 in the x direction and the y direction are different from each other.

In the first region, plural external connection terminals 16 are arranged in a lattice pattern at a pitch l₁ between two adjacent ones of the external connection terminals 16 in the x direction and the y direction (which will be referred to as first pitch l₁). In the second region, plural external connection terminals 16 are arranged in a lattice pattern at a pitch l₂ between two adjacent ones of the external connection terminals 16 in the x direction and the y direction (which will be referred to as second pitch l₂), and this pitch l₂ is larger than the pitch l₁.

In the first region, plural inductors 23 are arranged such that the air-core portion 23a of each inductor does not overlap with any of the external connection terminals 16 in the plan view. In the second region, plural inductors 29 are arranged such that the air-core portion 29a of each inductor does not overlap with any of the external connection terminals 16 in the plan view. The plan view refers to a view of the semiconductor device 40 when viewed from the direction Z+.

Unlike the case in which the inductors 203 are arranged to overlap with any of the external connection terminals 106 in the plan view as in the semiconductor device 100 illustrated in FIG. 1, the inductors 23 and 29 in the semiconductor device 40 of this embodiment are arranged so that each inductor does not overlap with any of the external connection terminals 16 in the plan view (refer to FIG. 16). In the semiconductor device 40 of this embodiment, the magnetic flux generated when a current flows through each of the inductors 23 and 29 does not penetrate the external connection terminals 16. As a result, the magnetic coupling between the inductors 23 and 29 and the external connection terminals 16 does not arise, and it is possible to effectively prevent the degradation of the characteristics of the inductors 23 and 29 due to the magnetic coupling.

The arrangement method of arranging external connection terminals and inductors in the semiconductor device 40 of this embodiment is essentially the same as the arrangement method illustrated in FIG. 6. However, the semiconductor device 40 of this embodiment includes the first region in which the external connection terminals 16 are arranged in a lattice pattern at the first pitch l₁, and the second region in which the external connection terminals 16 are arranged in a lattice pattern at the second pitch l₂ which is larger than the first pitch l₁. The steps 101-106 (S101-106) in the flowchart of FIG. 6 are performed for each of the first region and the second region respectively.

Specifically, in the flowchart of FIG. 6, in step 101, the arrangement of the external connection terminals 16 is determined for each of the first region and the second region respectively (S101).

Subsequently, in step 102, a maximum width d₁ of the air-core portions 23a of the inductors 23 arranged in the first region is determined to satisfy the following Inequality 6, and a maximum width d₂ of the air-core portions 29a of the inductors 29 arranged in the second region is determined to satisfy the following Inequality 7 (S102).

d₁≦l₁−r Inequality 6

where l₁ denotes a pitch between two adjacent ones of the external connection terminals 16 in the first region in the x direction and the y direction, and r denotes a diameter of the external connection terminals 16 in the plan view.

d₂≦l₂−r Inequality 7

where l₂ denotes a pitch between two adjacent ones of the external connection terminals 16 in the second region in the x direction and the y direction, and r denotes a diameter of the external connection terminals 16 in the plan view.

Subsequently, in step 103, first virtual lines 26a each passing a nearly central position between two adjacent ones of the external connection terminals 16 in the first region in a first direction are drawn, and third virtual lines 26c each passing a nearly central position between two adjacent ones of the external connection terminals 16 in the second region in the first direction are drawn (S103). For example, assuming that the first direction is set to the x direction, the first virtual lines 26a and the third virtual lines 26c, each passing a nearly central position between two adjacent ones of the external connection terminals 16 in the x direction, are drawn.

Subsequently, in step 104, second virtual lines 26b each passing a nearly central position between two adjacent ones of the external connection terminals 16 in the first region in a second direction nearly orthogonal to the first direction are drawn, and fourth virtual lines 26d each passing a nearly central position between two adjacent ones of the external connection terminals 16 in the second region in the second direction nearly orthogonal to the first direction are drawn (S104). For example, assuming that the second direction is set to the y direction nearly orthogonal to the x direction (which is the first direction), the second virtual lines 26b and the fourth virtual lines 26d each passing a nearly central position between two adjacent ones of the external connection terminals 16 in the y direction are drawn.

Subsequently, in step 105, a permissible range m₁ of the distances between one of the first virtual lines 26a and the second virtual lines 26b nearest to each of the inductors 23 and the center 23b of the inductor 23 is determined to satisfy the following Equation 8, and a permissible range m₂ of the distances between one of the third virtual lines 26c and the fourth virtual lines 26d nearest to each of the inductors 29 and the center 29b of the inductor 29 is determined to satisfy the following Equation 9 (S105).

m₁={l₁−(d₁+r)}/2 Equation 8

where l₁ denotes a pitch between two adjacent ones of the external connection terminals 16 in the x direction and the y direction, r denotes a diameter of the external connection terminals 16 in the plan view, and d₁ denotes the maximum width of the air-core portions 23a of the inductors 23.

m₂={l₂−(d₂+r)}/2 Equation 9

where l₂ denotes a pitch between two adjacent ones of the external connection terminals 16 in the x direction and the y direction, r denotes a diameter of the external connection terminals 16 in the plan view, and d2 denotes the maximum width of the air-core portions 29a of the inductors 29.

Subsequently, in step 106, a distance na₁ between the center 23b of the inductor 23 and the first virtual line 26a nearest to the inductor, and a distance nb₁ between the center 23b of the inductor 23 and the second virtual line 26b nearest to the inductor are determined. The distances na₁ and nb₁ are determined so that the distances na₁ and nb₁ satisfy the following Inequalities 10 and 11 respectively. That is, the distances na₁ and nb₁ can take arbitrary values that fall within the permissible range m₁. The inductors 23 are arranged in accordance with the determined distances na₁ and nb₁.

Furthermore, in the step 106, a distance na₂ between the center 29b of the inductor 29 and the third virtual line 26c nearest to the inductor, and a distance nb₂ between the center 29b of the inductor 29 and the fourth virtual line 26d nearest to the inductor are determined. The distances na₂ and nb₂ are determined so that the distances na₂ and nb₂ satisfy the following Inequalities 12 and 13 respectively. That is, the distances na₂ and nb₂ can take arbitrary values that fall within the permissible range m₂. The inductors 29 are arranged in accordance with the determined distances na₂ and nb₂ (S106).

na₁≦m₁ Inequality 10

where m₁ denotes a permissible range of the distances between the center 23b of each inductor 23 and one of the first virtual lines 26a and the second virtual lines 26b nearest to the inductor 23.

nb₁≦m₁ Inequality 11

where m₁ denotes a permissible range of the distances between the center 23b of each inductor 23 and one of the first virtual lines 26a and the second virtual lines 26b nearest to the inductor 23.

na₂≦m₂ Inequality 12

where m₂ denotes a permissible range of the distances between the center 29b of each inductor 29 and one of the third virtual lines 26c and the fourth virtual lines 26d nearest to the inductor 29.

nb₂≦m₂ Inequality 13

where m₂ denotes a permissible range of the distances between the center 29b of each inductor 29 and one of the third virtual lines 26c and the fourth virtual lines 26d nearest to the inductor 29.

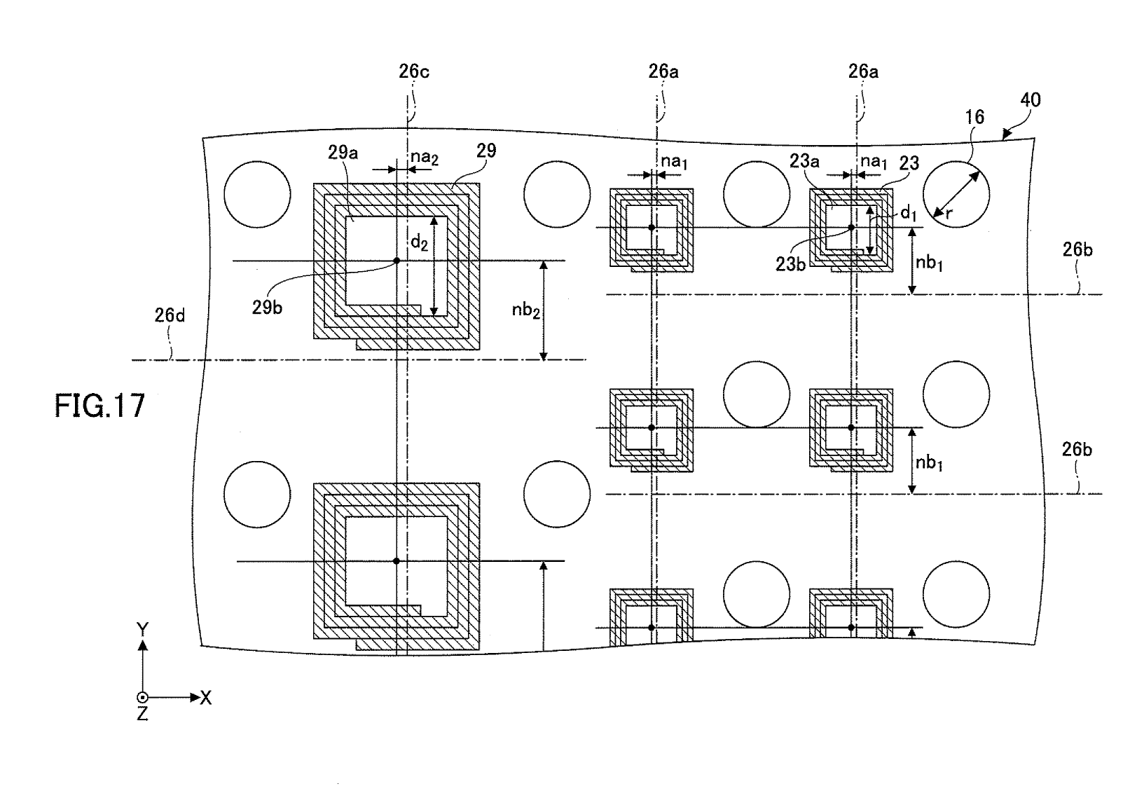

FIG. 17 is a diagram illustrating the state in which the inductors are arranged. In FIG. 17, the elements which are the same as corresponding elements in FIG. 16 are designated by the same reference numerals, and a description thereof will be omitted. In accordance with the flowchart of FIG. 6, the inductors 23 and 29 are arranged as illustrated in FIG. 17.

If the inductors 23 are arranged such that at least one of the distances na₁ and nb₁ falls within the permissible range m₁, the distances with respect to the respective inductors 23 may be different. In such a case, the inductors 23 are arranged in an irregular formation with respect to the first virtual lines 26a and the second virtual lines 26b. If the inductors 29 are arranged such that at least one of the distances na₂ and nb₂ falls within the permissible range m₂, the distances with respect to the respective inductors 29 may be different. In such a case, the inductors 29 are arranged in an irregular formation with respect to the third virtual lines 26c and the fourth virtual lines 26d.

In order to satisfy the condition that the outer periphery of the air-core portion 23a of the inductor 23 and the external connection terminals 16 do not overlap with each other in the plan view, it is sufficient that at least one of the distance na₁ and the distance nb₁ satisfies the Inequality 10 or the Inequality 11. Of course, both the distances na₁ and nb₁ may satisfy the Inequality 10 and the Inequality 11. When either the distance na₁ or the distance nb₁ is equal to zero, the distance between the outer periphery of the air-core portion 23a and the external connection terminal 16 may be increased to a comparatively large value.

When the distance na₁=the distance nb₁=0, the center 23b of the inductor 23 is located at the intersection of the first virtual line 26a and the second virtual line 26b. At this time, the distance between the outer periphery of the air-core portion 23a of the inductor 23 and the external connection terminal 16 arranged in the vicinity of the inductor 23 is equal to the maximum, and the arrangement of the inductor 23 at this time is in the most desirable state for preventing the magnetic coupling between the inductor 23 and the external connection terminal 16.

In order to satisfy the condition that the outer periphery of the air-core portion 29a of the inductor 29 and the external connection terminal 16 do not overlap with each other in the plan view, it is sufficient that at least one of the distance na₂ and the distance nb₂ satisfies the Inequality 12 or the Inequality 13. Of course, both the distances na₂ and nb₂ may satisfy the Inequality 12 and the Inequality 13. When either the distance na₂ or the distance nb₂ is equal to zero, the distance between the outer periphery of the air-core portion 29a and the external connection terminal 16 may be increased to a comparatively large value.

When the distance na₂=the distance nb₂=0, the center 29b of the inductor 29 is located at the intersection of the third virtual line 26c and the fourth virtual line 26d. At this time, the distance between the outer periphery of the air-core portion 29a of the inductor 29 and the external connection terminal 16 arranged in the vicinity of the inductor 29 is equal to the maximum, and the arrangement of the inductor 29 at this time is in the most desirable state for preventing the magnetic coupling between the inductor 29 and the external connection terminal 16.

The semiconductor device of the second embodiment of the present disclosure provides advantageous features that are similar to those of the first embodiment described above. In the semiconductor device of this embodiment including two distinct regions in which respective pitches between two adjacent ones of the external connection terminals in the x direction and the y direction differ from each other, the maximum width of the air-core portions of the inductors and the arrangement of the inductors in each of the regions can be optimized.

### Modification of First Embodiment

In the first embodiment, as illustrated in FIG. 11, the semiconductor device in which the inductors 23 are arranged so that the distance na between the center 23b of each inductor 23 and the first virtual line 26a nearest to the inductor, and the distance nb between the center 23b of each inductor 23 and the second virtual line 26b nearest to the inductor are the same for all the inductors 23 is illustrated. However, as previously described, it is sufficient that at least one of the distances na and nb falls within the permissible range m, and the distances na and nb with respect to the respective inductors 23 may be different. In a modification of the first embodiment, an example in which the distances na and nb with respect to the respective inductors 23 are different and the inductors 23 are arranged in an irregular formation with respect to the first virtual lines 26a and the second virtual lines 26b is illustrated.

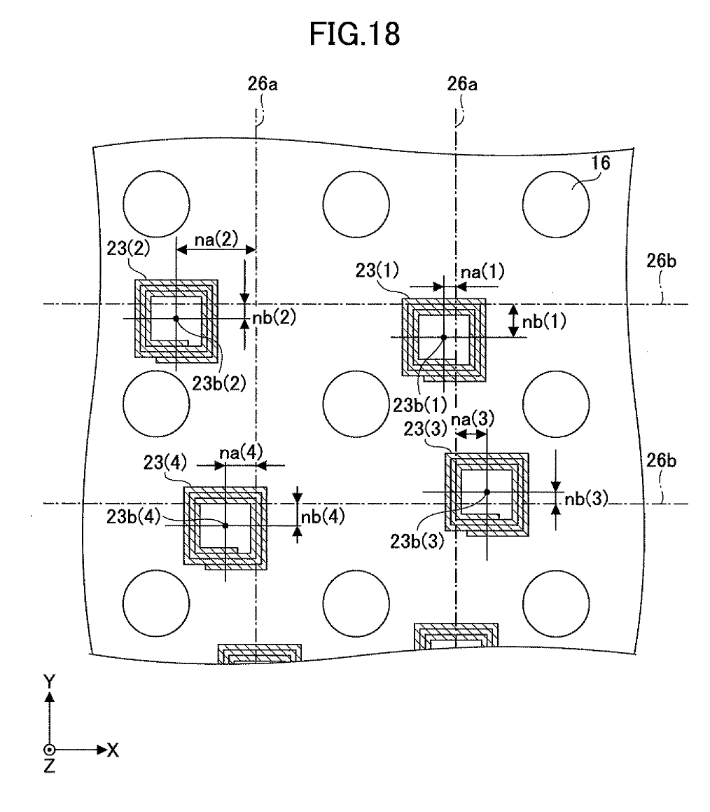

FIG. 18 is a diagram illustrating the state where the inductors are arranged in an irregular formation. In FIG. 18, the elements which are the same as corresponding elements in FIG. 11 are designated by the same reference numerals, and a description thereof will be omitted. In FIG. 18, it is assumed that n inductors 23 (where n is a natural number), including inductors not illustrated, are arranged. For the sake of convenience, the n inductors 23 will be referred to as inductors 23(1) to 23(n), and the centers of the n inductors 23 will be referred to as centers 23b(1) to 23b(n) respectively. It is assumed that na(1) to na(n) denote the respective distances between each of the centers 23b(1) to 23b(n) of the inductors 23(1) to 23(n) and the first virtual line 26a nearest to the inductor, and nb(1) to nb(n) denote the respective distances between each of the centers 23b(1) to 23b(n) of the inductors 23(1) to 23(n) and the second virtual line 26b nearest to the inductor.

The distances na(1) to na(n) are set to different values respectively. The distances nb(1) to nb(n) are set to different values respectively. However, at least one of the distances na(1) to na(n) and the distances nb(1) to nb(n) are set to values that fall within the permissible range m. Some of the distances na(1) to na(n) may be set to the same value, and some of the distances nb(1) to nb(n) may be set to the same value.

The distances na(1) to na(n) and the distances nb(1) to nb(n) are determined in accordance with the flowchart of FIG. 6. The point of this modification differing from the previously described first embodiment is that, in step 106 of the flowchart of FIG. 6, the distances na(1) to na(n) and the distances nb(1) to nb(n) are determined for each of the inductors 23(1) to 23(n). In this manner, each of the inductors 23 (the inductors 23(1) to 23(n)) can be arranged in an irregular formation with respect to the first virtual lines 26a and the second virtual lines 26b.

As described in the foregoing, the semiconductor device of this modification provides advantageous features that are similar to those of the first embodiment described above. In the semiconductor device of this modification, the inductors are arranged in an irregular formation with respect to the first virtual lines and the second virtual lines, and the flexibility of arrangement of the components in the semiconductor device can be increased.

The present disclosure is not limited to the above-described embodiments, and variations and modifications may be made without departing from the scope of the present disclosure.

For example, in the foregoing embodiments and modifications, the present disclosure is applied to the semiconductor devices of the wafer-level chip-size package (WLCSP). Alternatively, the present disclosure may also be applicable to other semiconductor devices.

In the modification of the first embodiment, the example in which each of the inductors is arranged in an irregular formation with respect to the first virtual lines and the second virtual lines has been illustrated. Alternatively, the semiconductor device of the second embodiment including two distinct regions in which the pitches between the external connection terminals are different may be modified so that the inductors in the respective regions are arranged in an irregular formation with respect to the first virtual lines and/or the second virtual lines and the third virtual lines and/or the fourth virtual lines.

The present international application is based on and claims the benefit of foreign priority of Japanese Patent Application No. 2008-178308, filed on Jul. 8, 2008, the contents of which are incorporated herein by reference in their entirety.

### DESCRIPTION OF THE REFERENCE NUMERALS

10, 40 semiconductor device
11 semiconductor chip
12 internal connection terminal
13 first insulating layer
14 wiring pattern
15 second insulating layer
15x opening
16 external connection terminal
20, 30 semiconductor substrate
21 semiconductor integrated circuit
22 electrode pad
23, 23(1)-23(n), 28, 29 inductor
23a, 27a, 28a, 29a air-core portion of inductor
23b, 23b(1)-23b(n), 29b center of inductor
24 protection film
25 magnetic flux
26a, 26b, 26c, 26d virtual line
27 inductor model
A semiconductor device formation area
B scribe region
C cut position
d, d1, d2 maximum width
I current
l₁, l₂ pitch
na, nb, na₁, nb₁, na₂, nb₂, na(1)-na(n),
nb(1)-nb(n) distance
p length
r diameter

1. An arrangement method of a semiconductor device which includes plural external connection terminals and plural inductors, the external connection terminals being arranged in a lattice pattern at a predetermined pitch, comprising:
a first step of determining the arrangement of the external connection terminals;
a second step of determining a maximum width of air-core portions of the inductors;
a third step of drawing first virtual lines each passing a nearly central position between two adjacent ones of the external connection terminals in a first direction;
a fourth step of drawing second virtual lines each passing a nearly central position between two adjacent ones of the external connection terminals in a second direction nearly orthogonal to the first direction;
a fifth step of determining a permissible range of distances between one of the first virtual lines and the second virtual lines nearest to each of the inductors and a center of the inductor; and
a sixth step of arranging the inductors such that at least one of a distance between one of the first virtual lines nearest to each of the inductors and the center of the inductor and a distance between one of the second virtual lines nearest to each of the inductors and the center of the inductor falls within the permissible range.

2. The arrangement method according to claim 1, wherein, assuming that d denotes the maximum width, na denotes the distance between one of the first virtual lines nearest to the inductor and the center of the inductor, and nb denotes the distance between one of the second virtual lines nearest to the inductor and the center of the inductor,
the maximum width d satisfies the Inequality 1 below and the distances na and nb satisfy the Inequalities 2 and 3 below respectively,
d≦l−r Inequality 1
na≦{l−(d+r)}/2 Inequality 2
nb≦{l−(d+r)}/2 Inequality 3
where l denotes a pitch between two adjacent ones of the external connection terminals in the first direction and the second direction and r denotes a maximum diameter of the external connection terminals in a plan view.

3. An arrangement method of a semiconductor device including plural external connection terminals and plural inductors, the semiconductor device having a first region in which the external connection terminals are arranged in a lattice pattern at a first pitch, and a second region in which the external connection terminals are arranged in a lattice pattern at a second pitch that is larger than the first pitch, the method comprising:
a first step of determining the arrangement of the external connection terminals in the first region and the second region;
a second step of determining a maximum width of air-core portions of the inductors arranged in the first region and a maximum width of air-core portions of the inductors arranged in the second region;
a third step of drawing first virtual lines in the first region, each passing a nearly central position between two adjacent ones of the external connection terminals in a first direction, and drawing third virtual lines in the second region, each passing a nearly central position between two adjacent ones of the external connection terminals in the first direction;
a fourth step of drawing second virtual lines in the first region, each passing a nearly central position between two adjacent ones of the external connection terminals in a second direction nearly orthogonal to the first direction, and drawing fourth virtual lines in the second region, each passing a nearly central position between two adjacent ones of the external connection terminals in the second direction;
a fifth step of computing, in the first region, a permissible range A of distances between one of the first virtual lines and the second virtual lines nearest to each of the inductors and a center of the inductor, and computing, in the second region, a permissible range B of distances between one of the third virtual lines and the fourth virtual lines nearest to each of the inductors and a center of the inductor; and
a sixth step of arranging the inductors in the first region such that at least one of a distance between one of the first virtual lines nearest to each of the inductors and the center of the inductor and a distance between one of the second virtual lines nearest to each of the inductors and the center of the inductor falls within the permissible range A, and arranging the inductors in the second region such that at least one of a distance between one of the third virtual lines nearest to each of the inductors and the center of the inductor and a distance between one of the fourth virtual lines nearest to each of the inductors and the center of the inductor falls within the permissible range B.

4. The arrangement method according to claim 3, wherein, assuming that d₁ denotes the maximum width in the first region, na₁ denotes the distance between one of the first virtual lines nearest to the inductor and the center of the inductor, and nb₁ denotes the distance between one of the second virtual lines nearest to the inductor and the center of the inductor,
the maximum width d₁ satisfies the Inequality 4 below and the distances na₁ and nb₁ satisfy the Inequalities 5 and 6 below respectively, and
wherein, assuming that d₂ denotes the maximum width in the second region, na₂ denotes the distance between one of the third virtual lines nearest to the inductor and the center of the inductor, and nb₂ denotes the distance between one of the fourth virtual lines nearest to the inductor and the center of the inductor,
the maximum width d₂ satisfies the Inequality 7 below and the distances na₂ and nb₂ satisfy the Inequalities 8 and 9 below respectively,
d₁≦l₁−r Inequality 4
na₁≦{l₁−(d₁+r)}/2 Inequality 5
nb₁≦{l₁−(d₁+r)}/2 Inequality 6
d₂≦l₂−r Inequality 7
na₂≦{l₂−(d₂+r)}/2 Inequality 8
nb₂≦{l₂−(d₂+r)}/2 Inequality 9
where l₁ denotes a pitch between two adjacent ones of the external connection terminals in the first region in the first direction and the second direction, l₂ denotes a pitch between two adjacent ones of the external connection terminals in the second region in the first direction and the second direction, and r denotes a maximum diameter of the external connection terminals in a plan view.

5. The arrangement method according to claim 1, wherein the inductors are arranged so that the center of each inductor is located on one of the first or second virtual lines, or on one of the third or fourth virtual lines.

6. The arrangement method according to claim 1, wherein the inductors are arranged so that the center of each inductor is located on one of intersections of the first virtual lines and the second virtual lines, or on one of intersections of the third virtual lines and the fourth virtual lines.

7. A semiconductor device comprising plural external connection terminals and plural inductors, the external connection terminals being arranged in a lattice pattern at a predetermined pitch,
wherein the inductors are arranged such that, assuming that d denotes a maximum width of air-core portions of the inductors, na denotes a distance between one of first virtual lines nearest to each of the inductors and a center of the inductor, each of the first virtual lines being drawn to pass a nearly central position between two adjacent ones of the external connection terminals in a first direction, and nb denotes a distance between one of second virtual lines nearest to each of the inductors and the center of the inductor, each of the second virtual lines being drawn to pass a nearly central position between two adjacent ones of the external connection terminals in a second direction nearly orthogonal to the first direction,
the maximum width d satisfies the Inequality 1 below and the distances na and nb satisfy the Inequalities 2 and 3 below respectively,
d≦l−r Inequality 1
na≦{l−(d+r)}/2 Inequality 2
nb≦{l−(d+r)}/2 Inequality 3
where l denotes a pitch between two adjacent ones of the external connection terminals in the first direction and the second direction and r denotes a maximum diameter of the external connection terminals in a plan view.

8. (canceled)

9. The semiconductor device according to claim 7, wherein the inductors are arranged so that the center of each inductor is located on one of the first or second virtual lines, or on one of the third or fourth virtual lines.

10. The semiconductor device according to claim 7, wherein the inductors are arranged so that the center of each inductor is located on one of intersections of the first virtual lines and the second virtual lines, or on one of intersections of the third virtual lines and the fourth virtual lines.

11. The semiconductor device according to claim 7, wherein the inductors are arranged in an irregular formation.

12. The arrangement method according to claim 3, wherein the inductors are arranged so that the center of each inductor is located on one of the first or second virtual lines, or on one of the third or fourth virtual lines.

13. The arrangement method according to claim 3, wherein the inductors are arranged so that the center of each inductor is located on one of intersections of the first virtual lines and the second virtual lines, or on one of intersections of the third virtual lines and the fourth virtual lines.
